(19) United States
(12) Patent Application Publication
(10) Pub. No.: US 2026/0090069 A1
(43) Pub. Date: Mar. 26, 2026

(54) METHOD OF MANUFACTURING SEMICONDUCTOR DEVICE

(71) Applicant: INSTITUTE OF MICROELECTRONICS, CHINESE ACADEMY OF SCIENCES, Beijing (CN)

(72) Inventors: Yongliang LI, Beijing (CN); Longyu SUN, Beijing (CN); Huaizhi LUO, Beijing (CN); Jun LUO, Beijing (CN)

(73) Assignee: INSTITUTE OF MICROELECTRONICS, CHINESE ACADEMY OF SCIENCES, Beijing (CN)

(21) Appl. No.: 19/283,883

(22) Filed: Jul. 29, 2025

(30) Foreign Application Priority Data
Sep. 13, 2024 (CN) 202411288780.4

(51) Int. Cl. H10D 84/01; H10D 30/01

(52) U.S. Cl. CPC H10D 84/0151; H10D 30/019; H10P 50/283; H10P 50/683

(57) ABSTRACT

The method of manufacturing a semiconductor device includes: forming a fin including first sacrificial layers and channel layers alternately stacked, and second and third sacrificial layers alternately stacked; a material of one of the second and third sacrificial layers including silicon or silicon germanium, and a material of the other one including silicon germanium or germanium; a difference in germanium content between the second and third sacrificial layers being less than 15%, and the second sacrificial layer being doped with an etching auxiliary agent; forming a mask straddling the fin; selectively removing the second sacrificial layers under an accelerated etching effect of the etching auxiliary agent to form a first dielectric filling region; forming first middle dielectric isolation layers in the first dielectric filling region; and removing the first sacrificial layers, the channel layers, the first middle dielectric isolation layers, and the third sacrificial layer not covered by the mask.

This application claims the benefit of priority to Chinese Patent Application No. 202411288780.4, filed on Sep. 13, 2024. The entire contents of this application are hereby incorporated herein by reference.

### TECHNICAL FIELD

The present disclosure relates to a field of semiconductor technology, and in particular, to a method of manufacturing a semiconductor device.

### BACKGROUND

Three-dimensional stacked complementary transistors include a N-type transistor and a P-type transistor vertically stacked, which reduces the lateral distance between the N-type transistor and the P-type transistor, and increases a valid channel width, thereby facilitating the improvement of the operating performance and integration of the semiconductor device.

### SUMMARY

The present disclosure provides a method of manufacturing a semiconductor device, including: forming a fin on a semiconductor substrate, where the fin includes first sacrificial layers and channel layers alternately stacked in a thickness direction of the semiconductor substrate, and second sacrificial layers and a third sacrificial layer alternately stacked in the thickness direction of the semiconductor substrate, the alternately stacked first sacrificial layers and the channel layers are located on both sides of the alternately stacked second sacrificial layers and the third sacrificial layer in the thickness direction of the semiconductor substrate; a bottom film layer and a top film layer among the alternately stacked first sacrificial layers and the channel layers are the first sacrificial layers, and a bottom film layer and a top film layer among the alternately stacked second sacrificial layers and the third sacrificial layer are the second sacrificial layers; a material of one of the second sacrificial layer and the third sacrificial layer includes silicon or silicon germanium, and a material of the other of the second sacrificial layer and the third sacrificial layer includes silicon germanium or germanium; a difference in germanium content between the second sacrificial layers and the third sacrificial layers is less than 15%, and the second sacrificial layers are doped with an etching auxiliary agent; forming a mask straddling the fin; selectively removing the second sacrificial layers at least under an accelerated etching effect of the etching auxiliary agent to form a first dielectric filling region, and retaining the third sacrificial layer; forming first middle dielectric isolation layers in the first dielectric filling region; removing the first sacrificial layers, the channel layers, the first middle dielectric isolation layers, and the third sacrificial layer not covered by the mask; forming a first source region and a first drain region on both sides of the remaining first sacrificial layers and channel layer located below the remaining first middle dielectric isolation layers, respectively; forming an insulating layer on the first source region and the first drain region; and forming a second source region and a second drain region on the insulating layer and on both sides of the remaining first sacrificial layers and channel layer located above the remaining first middle dielectric isolation layers, respectively, where a conductivity type of the second source region and the second drain region is opposite to a conductivity type of the first source region and the first drain region.

In an example, the above-described etching auxiliary agent is an N-type dopant.

In an example, the method further includes selectively removing the second sacrificial layers by using a wet etching process or an isotropic dry etching process.

In an example, a doping concentration of the etching auxiliary agent in the above-described second sacrificial layers is greater than or equal to 1E18cm⁻³ and less than or equal to 1E19cm⁻³.

In an example, in a case that the second sacrificial layers are selectively removed by using a wet etching process, a wet etching solution includes a mixed solution of hydrofluoric acid and hydrogen peroxide.

In an example, in a case that the second sacrificial layers are selectively removed by using a dry etching process, an etching gas includes a mixed gas of CF₄, O₂, and He.

In an example, a thickness of the above-described second sacrificial layer and/or the above-described third sacrificial layer is greater than or equal to 10 nm and less than or equal to 30 nm.

In an example, the method further includes doping the etching auxiliary agent into the second sacrificial layer by using an in-situ doping method.

In an example, a material of the above-described second sacrificial layer is the same as a material of the above-described third sacrificial layer.

In an example, a material of the above-described first sacrificial layer is the same as a material of the above-described third sacrificial layer.

In an example, after the removing the first sacrificial layers, the channel layers, the first middle dielectric isolation layers, and the third sacrificial layer not covered by the mask, and before the forming a first source region and a first drain region on both sides of the remaining first sacrificial layers and channel layer located below the remaining first middle dielectric isolation layers, respectively, the method further includes: removing, along a length direction of the fin, edge portions on both sides of each of the remaining first sacrificial layers to form a second dielectric filling region; and forming an inner spacer in the second dielectric filling region.

In an example, the above-described mask includes a sacrificial gate.

In an example, the method further includes forming, along a length direction of the fin, a gate spacer at least on both sides of the mask, when forming the first middle dielectric isolation layers in the dielectric filling region.

In an example, a material of the above-described first middle dielectric isolation layer includes at least one of SiN, SiCO, or SiCON.

In an example, after forming the second source region and the second drain region, the method further includes: forming an interlayer dielectric layer covering the semiconductor substrate; removing the mask; removing the remaining first sacrificial layers and removing the remaining third sacrificial layer; and forming a gate stack at least surrounding an outer periphery of the remaining channel layers.

In an example, a material of the first sacrificial layer is different from a material of the third sacrificial layer, where after removing the mask and before removing the remaining first sacrificial layers, the method further includes: removing the third sacrificial layer to form a third dielectric filling region; and forming a second middle dielectric isolation layer in the third dielectric filling region.

In an example, a material of the first sacrificial layer is different from a material of the third sacrificial layer, where after the forming first middle dielectric isolation layers in the first dielectric filling region, and before the forming a first source region and a first drain region on both sides of the remaining first sacrificial layers and channel layer located below the remaining first middle dielectric isolation layers, respectively, the method further includes: selectively removing the third sacrificial layer to form a third dielectric filling region; forming a second middle dielectric isolation layer in the third dielectric filling region; and removing the first sacrificial layers, the channel layers, the first middle dielectric isolation layers, and the second middle dielectric isolation layer not covered by the mask.

After forming the second source region and the second drain region, the method further includes: forming an interlayer dielectric layer covering the semiconductor substrate; removing the mask; removing the remaining first sacrificial layers; and forming a gate stack surrounding an outer periphery of the remaining channel layers.

In an example, a material of the above-described second middle dielectric isolation layer is the same as a material of the above-described first middle dielectric isolation layer.

In an example, a dielectric constant of a material of the above-described second middle dielectric isolation layer is less than a dielectric constant of a material of the above-described first middle dielectric isolation layer.

In an example, a material of the first middle dielectric isolation layer includes at least one of SiO₂, SiN, SiCO, SiCON, or SiO₂—SiF₄.

### BRIEF DESCRIPTION OF THE DRAWINGS

The accompanying drawings described herein are intended to provide a further understanding of the present disclosure and constitute a part of the present disclosure, and the schematic embodiments of the present disclosure and the description thereof are intended to explain the present disclosure and are not intended to be unduly limiting the present disclosure, in which:

FIG. 1 shows a flow chart of a method of manufacturing a semiconductor device provided by an embodiment of the present disclosure;

FIG. 2 shows a first schematic structural diagram of a semiconductor device manufactured by the manufacturing method provided by an embodiment of the present disclosure during a manufacturing process;

FIG. 3 shows a second schematic structural diagram of a semiconductor device manufactured by the manufacturing method provided by an embodiment of the present disclosure during a manufacturing process;

FIG. 4 shows a third schematic structural diagram of a semiconductor device manufactured by the manufacturing method provided by an embodiment of the present disclosure during a manufacturing process;

FIG. 5 shows a fourth schematic structural diagram of a semiconductor device manufactured by the manufacturing method provided by an embodiment of the present disclosure during a manufacturing process;

FIG. 6 shows a fifth schematic structural diagram of a semiconductor device manufactured by the manufacturing method provided by an embodiment of the present disclosure during a manufacturing process;

FIG. 7 shows a sixth schematic structural diagram of a semiconductor device manufactured by the manufacturing method provided by an embodiment of the present disclosure during a manufacturing process;

FIG. 8 shows a seventh schematic structural diagram of a semiconductor device manufactured by the manufacturing method provided by an embodiment of the present disclosure during a manufacturing process;

FIG. 9 shows an eighth schematic structural diagram of a semiconductor device manufactured by the manufacturing method provided by an embodiment of the present disclosure during a manufacturing process;

FIG. 10 shows a ninth schematic structural diagram of a semiconductor device manufactured by the manufacturing method provided by an embodiment of the present disclosure during a manufacturing process;

FIG. 11 shows a tenth schematic structural diagram of a semiconductor device manufactured by the manufacturing method provided by an embodiment of the present disclosure during a manufacturing process;

FIG. 12 shows an eleventh schematic structural diagram of a semiconductor device manufactured by the manufacturing method provided by an embodiment of the present disclosure during a manufacturing process;

FIG. 13 shows a twelfth schematic structural diagram of a semiconductor device manufactured by the manufacturing method provided by an embodiment of the present disclosure during a manufacturing process;

FIG. 14 shows a thirteenth schematic structural diagram of a semiconductor device manufactured by the manufacturing method provided by an embodiment of the present disclosure during a manufacturing process;

FIG. 15 shows a fourteenth schematic structural diagram of a semiconductor device manufactured by the manufacturing method provided by an embodiment of the present disclosure during a manufacturing process;

FIG. 16 shows a fifteenth schematic structural diagram of a semiconductor device manufactured by the manufacturing method provided by an embodiment of the present disclosure during a manufacturing process;

FIG. 17 shows a sixteenth schematic structural diagram of a semiconductor device manufactured by the manufacturing method provided by an embodiment of the present disclosure during a manufacturing process;

FIG. 18 shows a seventeenth schematic structural diagram of a semiconductor device manufactured by the manufacturing method provided by an embodiment of the present disclosure during a manufacturing process;

FIG. 19 shows an eighteenth schematic structural diagram of a semiconductor device manufactured by the manufacturing method provided by an embodiment of the present disclosure during a manufacturing process;

FIG. 20 shows a nineteenth schematic structural diagram of a semiconductor device manufactured by the manufacturing method provided by an embodiment of the present disclosure during a manufacturing process;

FIG. 21 shows a twentieth schematic structural diagram of a semiconductor device manufactured by the manufacturing method provided by an embodiment of the present disclosure during a manufacturing process;

FIG. 22 shows a twenty-first schematic structural diagram of a semiconductor device manufactured by the manufacturing method provided by an embodiment of the present disclosure during a manufacturing process;

FIG. 23 shows a twenty-second schematic structural diagram of a semiconductor device manufactured by the manufacturing method provided by an embodiment of the present disclosure during a manufacturing process;

FIG. 24 shows a twenty-third schematic structural diagram of a semiconductor device manufactured by the manufacturing method provided by an embodiment of the present disclosure during a manufacturing process;

FIG. 25 shows a twenty-fourth schematic structural diagram of a semiconductor device manufactured by the manufacturing method provided by an embodiment of the present disclosure during a manufacturing process;

FIG. 26 shows a twenty-fifth schematic structural diagram of a semiconductor device manufactured by the manufacturing method provided by an embodiment of the present disclosure during a manufacturing process;

FIG. 27 shows a twenty-sixth schematic structural diagram of a semiconductor device manufactured by the manufacturing method provided by an embodiment of the present disclosure during a manufacturing process;

FIG. 28 shows a twenty-seventh schematic structural diagram of a semiconductor device manufactured by the manufacturing method provided by an embodiment of the present disclosure during a manufacturing process;

FIG. 29 shows a twenty-eighth schematic structural diagram of a semiconductor device manufactured by the manufacturing method provided by an embodiment of the present disclosure during a manufacturing process;

FIG. 30 shows a twenty-ninth schematic structural diagram of a semiconductor device manufactured by the manufacturing method provided by an embodiment of the present disclosure during a manufacturing process;

FIG. 31 shows a thirtieth schematic structural diagram of a semiconductor device manufactured by the manufacturing method provided by an embodiment of the present disclosure during a manufacturing process; and

FIG. 32 shows a thirty-first schematic structural diagram of a semiconductor device manufactured by the manufacturing method provided by an embodiment of the present disclosure during a manufacturing process.

### DETAILED DESCRIPTION OF EMBODIMENTS

Hereinafter, embodiments of the present disclosure will be described with reference to the accompanying drawings. However, it should be understood that these descriptions are only exemplary and are not intended to limit the scope of the present disclosure. In addition, in the following illustration, descriptions of well-known structures and technologies are omitted to avoid unnecessarily confusing the concepts of the present disclosure.

Various schematic structural diagrams according to the embodiments of the present disclosure are shown in the drawings. These drawings are not drawn to scale, in which some details are enlarged and some details may be omitted for the purpose of clear expression. The shapes, the relative sizes and the positional relationships of various regions and layers shown in the drawings are only exemplary, and may actually be deviated due to manufacturing tolerances or technical limitations. Moreover, those skilled in the art may additionally design regions/layers with different shapes, sizes and relative positions according to actual needs.

In the context of the present disclosure, when a layer/element is described to be “on” a further layer/element, the layer/element may be directly on the further layer/element, or there may be an intermediate layer/element therebetween. In addition, if a layer/element is “on” a further layer/element in one orientation, the layer/element may be “below” the further layer/element when the orientation is reversed. In order to make the technical problems to be solved, technical solutions and beneficial effects in the present disclosure more apparent and understandable, the present disclosure is further described in detail below in combination with the drawings and embodiments. It should be understood that the specific embodiments described herein are merely for illustration of the present disclosure and are not intended to limit the present disclosure.

In addition, terms “first” and “second” are only used for descriptive purposes and are not to be construed as indicating or implying relative importance or implicitly indicating the number of technical features indicated. Therefore, a feature defined with “first” or “second” may, explicitly or implicitly, include one or more of the feature. In the description of the present disclosure, “a plurality of” means two or more, unless explicitly and specifically defined otherwise. “Several” means one or more, unless explicitly and specifically defined otherwise.

In the description of the present disclosure, it should be noted that, unless otherwise explicitly stated or defined, terms “installed”, “connected”, and “coupled” should be interpreted broadly, and for example, they may refer to fixed connections, detachable connections, or integral connections; mechanical connections or electrical connections; direct connections, or indirect connections via intermediate media; internal communications between two elements or an interaction relationship between two elements. Those of ordinary skill in the art may understand the specific meanings of the above terms in the present disclosure according to specific situations.

Three-dimensional stacked complementary transistors include a N-type transistor and a P-type transistor vertically stacked, which reduces the lateral distance between the N-type transistor and the P-type transistor, and increases a valid channel width, thereby facilitating the improvement of the operating performance and integration of the semiconductor device.

However, the existing manufacturing method of the three-dimensional stacked complementary transistors has high requirements for processing technology, which makes the manufacturing of the three-dimensional stacked complementary transistors difficult, resulting in a low yield of the three-dimensional stacked complementary transistors, and is not conducive to improving the operating performance of three-dimensional stacked complementary transistors. The existing manufacturing method of the three-dimensional stacked complementary transistors mainly has the following two integration solutions.

The first solution is to manufacture the three-dimensional stacked complementary transistors in a monolithic manner. For example, taking the N-type transistor and the P-type transistor being gate-all-around transistors, and the P-type transistor being located above the N-type transistor as an example, the process of manufacturing the three-dimensional stacked complementary transistors by the existing manufacturing method is described as follows: first, a fin is formed on a semiconductor substrate. The fin includes at least two stacked layers. Each stacked layer includes a sacrificial layer and a channel layer on the sacrificial layer, and the materials of the sacrificial layer and the channel layer are both semiconductor materials. Next, a sacrificial gate and a spacer are formed to straddle the portion of the fin. The fin is selectively etched using the sacrificial gate and the spacer as the mask to remove the portion of the fin exposed outside the sacrificial gate and the spacer. Then, a first semiconductor material for manufacturing a source region and a drain region included in the N-type transistor is formed on the semiconductor substrate. At this point, since the remaining portions of the sacrificial layer and the channel layer corresponding to the N-type transistor and the P-type transistor after being etched are exposed, and the remaining portions of the sacrificial layer and the channel layer may be used as seed layers for epitaxial growth of the first semiconductor material, the first semiconductor material is formed not only on both sides of the remaining portions of the sacrificial layer and the channel layer corresponding to the N-type transistor after being etched, but also on both sides of the remaining portions of the sacrificial layer and the channel layer corresponding to the P-type transistor after being etched. Next, it is required to remove the first semiconductor material located on both sides of the remaining portions of the sacrificial layer and the channel layer corresponding to the P-type transistor after being etched, and the remaining portions of the first semiconductor material form the source region and the drain region included in the N-type transistor. Then, an epitaxial isolation layer covering the surface of the source region and the drain region included in the N-type transistor facing away from the substrate is formed, and the source region and the drain region of the P-type transistor are formed on the epitaxial isolation layer by an epitaxial growth process. Finally, the sacrificial gate and a portion of the sacrificial layer located within the gate formation region are removed, and a gate stack surrounding the outer periphery of the channel region is formed to obtain the three-dimensional stacked complementary transistors.

The second solution is to manufacture the three-dimensional stacked complementary transistors in a sequential manner, in which the bottom transistor is formed according to the conventional manufacturing process of semiconductor device, and after the corresponding contact electrode of the bottom transistor is formed, a semiconductor layer is covered on the top of the bottom transistor by a wafer transfer method using wafer-to-wafer bonding technology. Then, a top transistor is integrated based on the semiconductor layer, and the top gate and the bottom gate are connected to obtain the three-dimensional stacked complementary transistors.

As can be seen from the manufacturing process of the first solution described above, in the first solution of manufacturing the three-dimensional stacked complementary transistors, it is required to form a channel layer and a sacrificial layer of a semiconductor material by an epitaxial process. However, the problem that stress distribution and stress matching between films need to be considered in epitaxial material brings great technical challenges to the manufacturing of three-dimensional stacked complementary transistors. Furthermore, in the above-described first manufacturing method, the aspect ratio of the structure is large, and when manufacturing the middle dielectric isolation (MDI) for isolating upper and lower elements, after forming a sacrificial gate and performing source-drain etching, the depth-width ratio of the gap between the adjacent fins is large, which easily leads to difficulty in completely removing the insulating dielectric material located at the bottom of the gap between the adjacent fins after filling the insulating dielectric material for manufacturing the middle dielectric isolation, thereby affecting the formation of the source region and the drain region of the subsequent lower element and affecting the device performance. Moreover, in order to form the above-described middle dielectric isolation, it is necessary to add at least one sacrificial layer of another material. In the current manufacturing methods, the epitaxially grown channel layers and sacrificial layers involve at least three different semiconductor materials, which further increases the difficulty of epitaxy. Second, due to the limitation of the epitaxial critical thickness, when there is a large difference between different materials, the thickness of the film formed in a single step may only be reduced to ensure the quality of the formed film. Based on this, if only a fixed number of overlapping sacrificial layers are formed at the position corresponding to the middle dielectric isolation, the thickness of the insulating layer used to isolate he first source region and the first drain region from the second source region and the second drain region will be relatively small, and it is difficult to prevent leakage. If the insulating layer is ensured to have sufficient thickness, it is required to alternately form more layers of sacrificial layers, resulting in a complex process.

If the middle dielectric isolation is not formed, on the one hand, leakage or interference between the upper and lower elements will be affected; on the other hand, when the upper and lower elements adopt different metal gate materials, it is required to fill the gate formation region with the protective material such as spin-coated carbon and perform back etching to expose only the nanostructure of the upper element; if there is no middle dielectric isolation at this point, when the above protective material is etched back, the portion of the protective material located below the nanostructure included in the upper element is difficult to be completely removed, thereby affecting the formation of the subsequent first layer of metal gate and the device performance.

As for the above-described second method of manufacturing the three-dimensional stacked complementary transistors, the bonding solution used has technical challenges such as alignment, and the requirements for the process are also high, which makes the manufacturing of three-dimensional stacked complementary transistors more difficult, and is not conducive to improve the operating performance of the three-dimensional stacked complementary transistors.

In order to solve the above-described technical problems, embodiments of the present disclosure provide a method of manufacturing a semiconductor device. In the method provided by the embodiments of the present disclosure, the difference of germanium content in the second sacrificial layer and the third sacrificial layer is less than 15%; at this point, the material difference between the second sacrificial layer and the third sacrificial layer is small, which may alleviate the problems in the related art such as the need to consider stress distribution and stress matching between films due to the large material difference between the second sacrificial layer and the third sacrificial layer. In addition, the formation operation of the first middle dielectric isolation layer is performed in advance before the source-drain etching is performed, so that the difficulty of manufacturing a middle dielectric isolation layer is reduced, the formation of the first source region and the first drain region of the subsequent lower layer element and the contact of the first source region and the first drain region with the first channel region respectively are not affected, and the yield of the manufactured semiconductor device is increased.

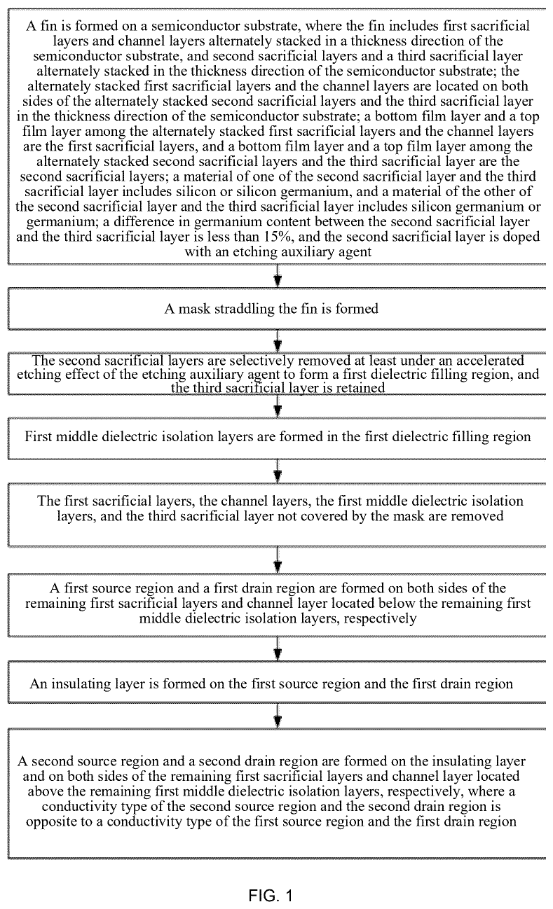

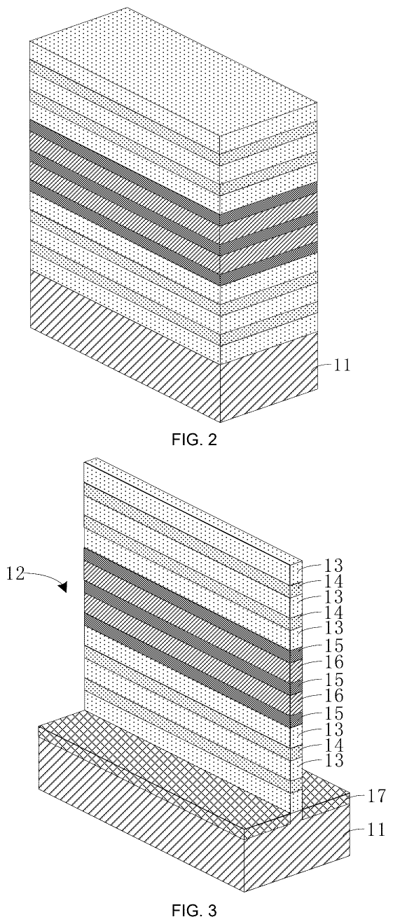

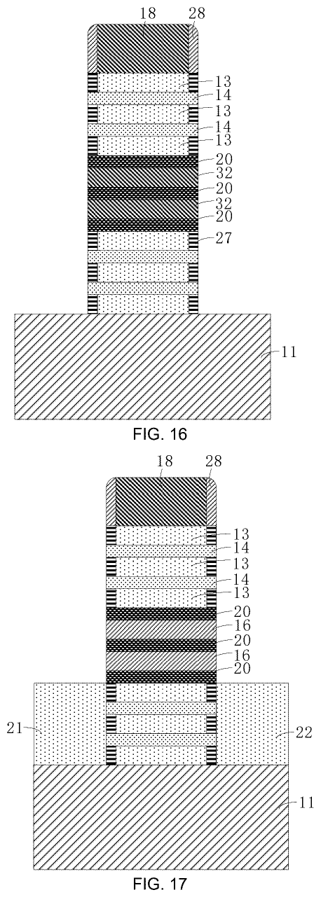

As shown in FIG. 1, embodiments of the present disclosure provide a method of manufacturing a semiconductor device. The following describes the manufacturing process according to the cross-sectional views or perspective views of the operations shown in FIG. 2 to FIG. 32. For example, the method includes the following steps.

As shown in FIG. 2 and FIG. 3, a fin 12 is formed on a semiconductor substrate 11. The fin 12 includes first sacrificial layers 13 and channel layers 14 alternately stacked in a thickness direction of the semiconductor substrate 11, and second sacrificial layers 15 and third sacrificial layers 16 alternately stacked in the thickness direction of the semiconductor substrate 11. The alternately stacked first sacrificial layers 13 and the channel layers 14 are located on both sides of the alternately stacked second sacrificial layers 15 and third sacrificial layers 16 in the thickness direction of the semiconductor substrate 11. A bottom film layer and a top film layer among the alternately stacked first sacrificial layers 13 and the channel layers 14 are the first sacrificial layers 13. A bottom film layer and a top film layer among the alternately stacked second sacrificial layers 15 and third sacrificial layers 16 are the second sacrificial layers 15. A material of one of the second sacrificial layer 15 and the third sacrificial layer 16 includes silicon or silicon germanium, and a material of the other of the second sacrificial layer 15 and the third sacrificial layer 16 includes silicon germanium or germanium. A difference in germanium content between the second sacrificial layer 15 and the third sacrificial layer 16 is less than 15%, and the second sacrificial layer 15 is doped with an etching auxiliary agent.

For example, the alternately stacked first sacrificial layers and the channel layers located below the alternately stacked second sacrificial layers and third sacrificial layers in the thickness direction of the semiconductor substrate are used to manufacture the lower element in the three-dimensional stacked complementary transistors. Based on this, the number of layers and materials of the alternately stacked first sacrificial layers and the channel layers located below the alternately stacked second sacrificial layers and third sacrificial layers may be determined according to the requirements for the lower layer element in the actual application scenario.

The number of channel layers located below the alternately stacked second sacrificial layers and third sacrificial layers may be one or more. The material of the channel layer may include any semiconductor material such as silicon, silicon germanium, or germanium. In addition, since the first channel region included in the lower element needs to be released by removing the first sacrificial layer covered by the mask in the subsequent process, and the first sacrificial layer and the third sacrificial layer need to be retained when the second sacrificial layer is selectively removed, the material of the first sacrificial layer may be any semiconductor material having a certain etch selectivity ratio to the materials of the channel layer and the second sacrificial layer. For example, when the material of the channel layer is silicon and the material of the second sacrificial layer is silicon germanium, the material of the first sacrificial layer may be silicon germanium or germanium, and the contents of germanium in the first sacrificial layer and the second sacrificial layer are different.

In the actual application process, the material of the first sacrificial layer may be the same as the material of the third sacrificial layer; at this point, after the mask is subsequently removed, the remaining first sacrificial layer and third sacrificial layer may be removed, which reduces the material types of different film layers of the fin while improving the manufacturing efficiency, and further alleviates the problem that stress distribution and stress matching between films need to be considered in epitaxial materials, and reduces the manufacturing difficulty. Alternatively, the materials of the first sacrificial layer and the third sacrificial layer may be different. At this point, the first sacrificial layer and the third sacrificial layer are conveniently released respectively according to different actual requirements, and the applicability of the manufacturing method provided by the embodiments of the present disclosure in different application scenarios is improved.

As for the alternately stacked second sacrificial layers and third sacrificial layers described above, the first dielectric filling region used to manufacture the first middle dielectric isolation layers is subsequently released by removing the second sacrificial layers. The alternately stacked second sacrificial layers and third sacrificial layers are arranged for forming the first middle dielectric isolation layers on one hand, and for forming an insulating layer which is used for separating the first source region and the first drain region from the second source region and the second drain region respectively on the other hand, where the thickness of the insulating layer may be large enough to ensure that the insulating layer has high insulating property, and meanwhile, the filling difficulty of the first middle dielectric isolation layers may be reduced, especially when the first middle dielectric isolation layers and the gate spacer are formed simultaneously (to improve the manufacturing efficiency), the insulating dielectric material for manufacturing the gate spacer is prevented from being difficult to fill the first dielectric filling region with larger thickness, the manufacturing difficulty is reduced, and the yield of the semiconductor device is improved. Therefore, the thickness of the single-layer second sacrificial layer may refer to the thickness of the gate spacer, and the total thickness of the alternately stacked second sacrificial layers and third sacrificial layers may refer to the thickness of the insulating layer in the actual application scenario.

It should be noted that since the difference of germanium content in the second sacrificial layer and the third sacrificial layer is less than 15%, at this point, the material difference between the second sacrificial layer and the third sacrificial layer is small, and the corresponding lattice difference between the second sacrificial layer and the third sacrificial layer is also small. When epitaxially growing the materials for manufacturing the second sacrificial layer and the third sacrificial layer, the problems in the related art such as the need to consider stress distribution and stress matching between films due to the large material difference between the second sacrificial layer and the third sacrificial layer may be alleviated, and the limitation of the epitaxial critical thickness may be reduced. Based on this, the specific thickness of each of the second sacrificial layers and the third sacrificial layers may be determined according to the requirements of the number of layers of the second sacrificial layers and the third sacrificial layers alternately stacked and the thickness of the insulating layer in the actual application scenario, which is not specifically limited here.

Exemplarily, the thickness of the second sacrificial layer and/or the third sacrificial layer may be greater than or equal to 10 nm and less than or equal to 30 nm. For example, the thickness of the second sacrificial layer and/or the third sacrificial layer may be 10 nm, 12 nm, 15 nm, 18 nm, 20 nm, 25 nm, 28 nm, 30 nm, or the like.

In addition, in the embodiments of the present disclosure, the material of the second sacrificial layer may include silicon or silicon germanium, and the material of the third sacrificial layer may include silicon germanium or germanium; alternatively, the material of the second sacrificial layer may include silicon germanium or germanium, and the material of the third sacrificial layer may include silicon or silicon germanium. In addition, it can be understood that when the difference in germanium content in the second sacrificial layer and the third sacrificial layer is larger, the material difference between the second sacrificial layer and the third sacrificial layer is larger, and the etching selectivity ratio is larger. Further, the type of etching auxiliary agent doped in the second sacrificial layer and the doping concentration of the etching auxiliary agent doped in the second sacrificial layer also affect the etching rate of the second sacrificial layer. For example, when other factors are the same, the greater the concentration of the etching auxiliary agent doped in the second sacrificial layer, the greater the etching rate of the etching auxiliary agent to the second sacrificial layer when the second sacrificial layer is selectively etched, and the greater the etching selectivity ratio between the second sacrificial layer and the third sacrificial layer. Therefore, the respective germanium contents in the second sacrificial layer and the third sacrificial layer, the type of the etching auxiliary agent in the second sacrificial layer, and the doping concentration of the etching auxiliary agent in the second sacrificial layer may be determined according to the requirements for the etching selectivity ratio between the second sacrificial layer and the third sacrificial layer in the actual application scenario.

Exemplarily, the materials of the second sacrificial layer and the third sacrificial layer described above may be the same. For example, the second sacrificial layer and the third sacrificial layer may include silicon, silicon germanium, or germanium. The materials of the second sacrificial layer and the third sacrificial layer may also be different. For example, the difference in germanium content in the second sacrificial layer and the third sacrificial layer may be 1%, 1.5%, 2%, 2.5%, 3%, 3.5%, 4%, 5%, 6%, 7%, 8%, 9%, 10%, or the like.

Exemplarily, the above-described etching auxiliary agent may be an N-type dopant. For example, the above-described etching auxiliary agent may be phosphorus, arsenic, or the like.

Exemplarily, the doping concentration of the etching auxiliary agent in the second sacrificial layer may be greater than or equal to 1 E18cm⁻³ and less than or equal to 1 E19cm⁻³. For example, the doping concentration of the etching auxiliary agent in the second sacrificial layer may be 1 E18cm⁻³, 2 E18cm⁻³, 3 E18cm⁻³, 4 E18cm⁻³, 5 E18cm⁻³, 6 E18cm⁻³, 8 E18cm⁻³, 1 E19cm⁻³, or the like. In this case, when the doping concentration of the etching auxiliary agent in the second sacrificial layer is within the above-described range, which is beneficial to prevent the weak etching assistance effect of the etching auxiliary agent on the second sacrificial layer due to the low doping concentration, and further reduce the material difference between the second sacrificial layer and the third sacrificial layer. In addition, it is possible to prevent the difficulty of doping the etching auxiliary agent in the second sacrificial layer due to the high doping concentration, and to reduce the difficulty of manufacturing the semiconductor device.

In addition, the alternately stacked first sacrificial layers and channel layers located above the alternately stacked second sacrificial layers and third sacrificial layers in the thickness direction of the semiconductor substrate are used to manufacture the upper layer element in the three-dimensional stacked complementary transistors. Based on this, the number of layers and materials of the alternately stacked first sacrificial layers and the channel layers located above the alternately stacked second sacrificial layers and third sacrificial layers may be determined according to the requirements of the above-described upper layer element in the actual application scenario, and are not specifically limited here.

In the actual manufacturing process, as shown in FIG. 2, material layers for manufacturing the alternately stacked first sacrificial layers and the channel layers, and the alternately stacked second sacrificial layers and third sacrificial layers, may be formed in the thickness direction of the semiconductor substrate 11 by a process such as epitaxy. When forming the second sacrificial layer, an in-situ doping method may be adopted to dope the second sacrificial layer with an etching auxiliary agent to improve manufacturing efficiency. Alternatively, after the second sacrificial layer is formed, the second sacrificial layer may be doped by ion implantation, diffusion, or the like. Then, the above-described material layers and part of the semiconductor substrate are patterned by photolithography and etching processes to form fins. Next, as shown in FIG. 3, a shallow groove isolation structure 17 for defining the active region may be formed between adjacent fins using processes such as deposition and etching. The top height of the shallow trough isolation structure 17 is less than or equal to the bottom height of the first sacrificial layer 13 located on the bottom layer. The portion of the fin exposed outside the shallow groove isolation structure 17 is the fin 12.

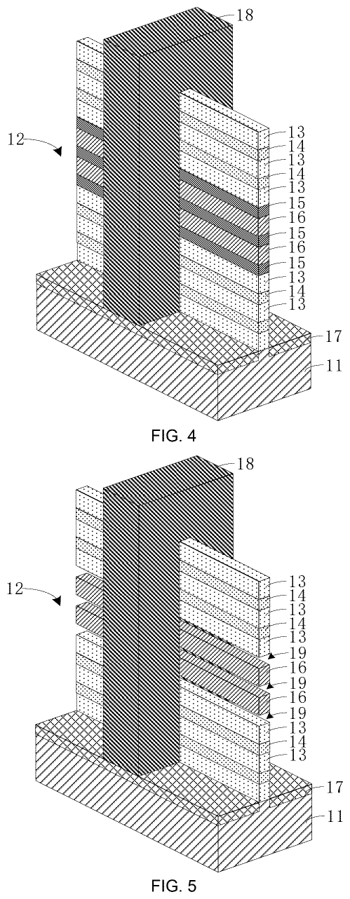

Next, as shown in FIG. 4, a mask 18 straddling the fin 12 is formed.

In the actual manufacturing process, a deposition process may be used to form a mask material covering the semiconductor substrate. Then, the mask material is selectively etched by photolithography and etching processes to form the above-described mask. The material of the mask may be set according to actual needs, as long as the material of the mask may play a mask protection role in the subsequent process.

Exemplarily, the above-described mask may include a sacrificial gate. The material of the sacrificial gate may include an easily removable material such as polysilicon. Second, the above-described mask may include a gate oxide layer and a sacrificial gate located on the gate oxide layer. The material of the gate oxide layer may include a material such as silicon oxide.

Next, as shown in FIG. 5, the second sacrificial layers 15 is selectively removed at least under an accelerated etching effect of the etching auxiliary agent to form the first dielectric filling region 19. The third sacrificial layer 16 is retained.

For example, the second sacrificial layer may be selectively removed by a process such as wet etching or isotropic dry etching. The specific type of etchant used and the etching conditions may be determined according to the type and doping concentration of the etching auxiliary agent, and the actual application scenario, and are not specifically limited here.

Exemplarily, in a case that the second sacrificial layers are selectively removed by using a wet etching process, a wet etching solution includes a mixed solution of hydrofluoric acid and hydrogen peroxide.

Exemplarily, in a case that the second sacrificial layers are selectively removed by using a dry etching process, an etching gas includes a mixed gas of CF₄, O₂, and He.

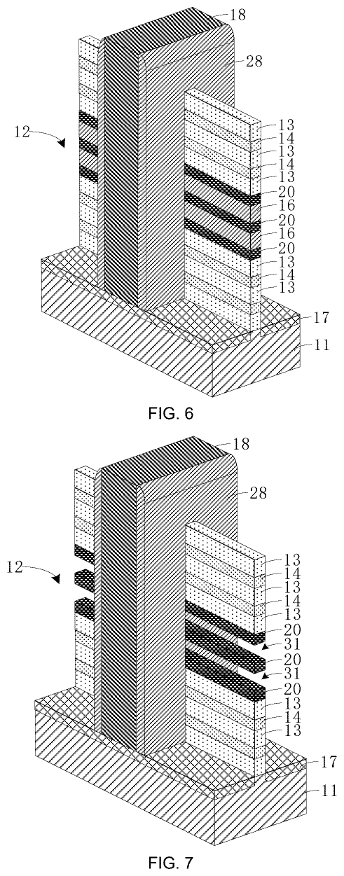

Next, as shown in FIG. 6, first middle dielectric isolation layers 20 are formed in the first dielectric filling region.

In the actual manufacturing process, the insulating dielectric material covering the semiconductor substrate may be formed by a process such as deposition. Then, the portion of the insulating dielectric material located outside the first dielectric filling region may be completely removed by using an etching process, and at this point, the first middle dielectric isolation layers may be formed based on the insulating dielectric material. Alternatively, a portion of the insulating dielectric material located in the first dielectric filling region and covering the area outside the sidewall of the mask may be completely removed, and at this point, the first middle dielectric isolation layers and the gate spacer may be formed based on the insulating dielectric material. In other words, as shown in FIG. 6, while the first middle dielectric isolation layers 20 are formed in the first dielectric filling region 19, the gate spacers 28 are formed at least on both sides of the mask 18 in the length direction of the fin 12, and at this point, the material of the gate spacers 28 and the material of the first middle dielectric isolation layers 20 are the same.

The material of the first middle dielectric isolation layer may include any insulating dielectric material as long as the material may be applied to the manufacturing method provided by the embodiments of the present disclosure.

Exemplarily, the material of the above-described first middle dielectric isolation layer includes at least one of SiN, SiCO, or SiCON.

Next, as shown in FIG. 7 to FIG. 10, the first sacrificial layers 13, the channel layers 14, the first middle dielectric isolation layers 20, and the third sacrificial layer 16 that are not covered by the mask 18 are removed.

In the actual manufacturing process, as shown in FIG. 6 and FIG. 9, after forming the first middle dielectric isolation layers 20, the first sacrificial layers 13, the channel layers 14, the first middle dielectric isolation layers 20, and the third sacrificial layer 16 that are not covered by the mask 18 may be removed together to facilitate the subsequent formation of the first source region, the first drain region, the second source region, and the second drain region.

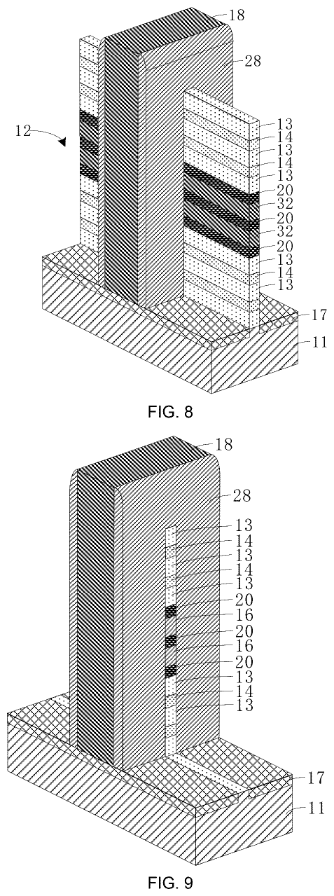

Alternatively, when the material of the first sacrificial layer is different from the material of the third sacrificial layer, as shown in FIG. 7, the third sacrificial layer may be selectively removed first to form the third dielectric filling region 31. Next, as shown in FIG. 8, a second middle dielectric isolation layer 32 is formed in the third dielectric filling region. Next, as shown in FIG. 10, the first sacrificial layers 13, the channel layers 14, the first middle dielectric isolation layers 20, and the second middle dielectric isolation layer 32 that are not covered by the mask 18 are removed. At this point, when the gate stack is subsequently formed, the gate stack is not filled in the gap between the two adjacent first middle dielectric isolation layers 20, thereby reducing the parasitic capacitance and further improving the operating performance of the manufactured semiconductor device.

The material of the second middle dielectric isolation layer may be the same as or different from the material of the first middle dielectric isolation layer. The specific material of the second middle dielectric isolation layer may be set according to actual needs.

Exemplarily, the dielectric constant of the material of the above-described second middle dielectric isolation layer may be less than the dielectric constant of the material of the first middle dielectric isolation layer, so as to further reduce the parasitic capacitance between the gate stack included in the upper layer element and the gate stack included in the lower layer element in the three-dimensional stacked complementary transistors, and improve the operating performance of the semiconductor device.

Exemplarily, the material of the above-described second middle dielectric isolation layer may include at least one of SiO₂, SiN, SiCO, SiCON, or SiO₂—SiF₄.

When the material of the first sacrificial layer is different from the material of the third sacrificial layer, the first sacrificial layers, the channel layers, the first middle dielectric isolation layers, and the third sacrificial layer that are not covered by the mask may be removed together after the first middle dielectric isolation layers are formed.

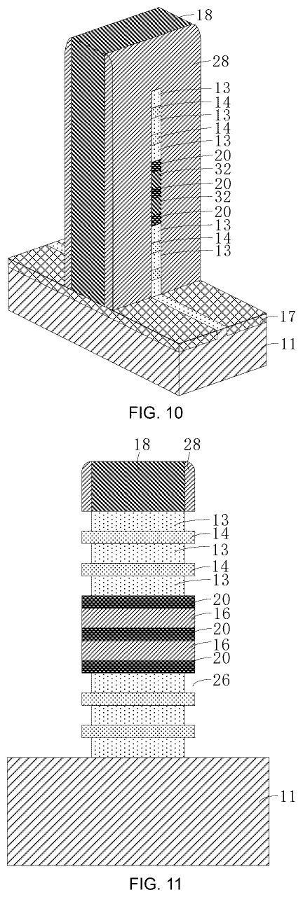

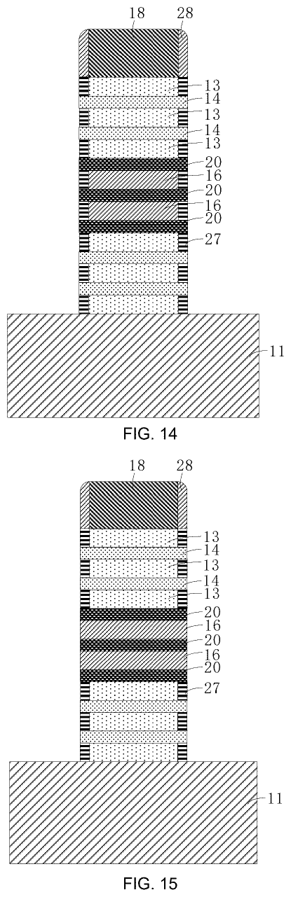

In addition, after removing the first sacrificial layers, the channel layers, the first middle dielectric isolation layers, and the third sacrificial layer that are not covered by the mask, before performing subsequent operations, the method may further include the following steps: as shown in FIG. 11 and FIG. 13, the edge portions on both sides of each of the remaining first sacrificial layers 13 are removed along the length direction of the fin by a process such as wet etching or dry etching to form the second dielectric filling region 26. Next, as shown in FIG. 14 to FIG. 16, the inner spacer 27 may be formed in the second dielectric filling region by a process such as deposition and etching. The inner spacer 27 may limit the length of the gate stack, which is beneficial to improve the operating performance of the semiconductor device. The material of the inner spacer 27 may include any insulating material such as silicon nitride, silicon oxynitride, or silicon oxycarbide as long as the material may be applied to the manufacturing method provided by the embodiments of the present disclosure.

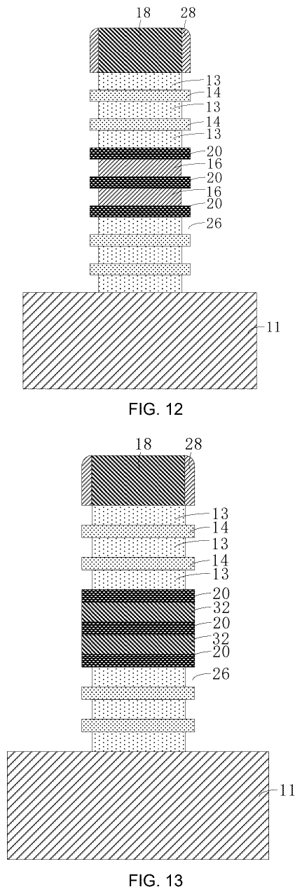

It should be noted that, as shown in FIG. 12 and FIG. 14, when the material of the first sacrificial layer 13 and the material of the third sacrificial layer 16 are the same, the inner spacer 27 is also formed on both sides of the remaining third sacrificial layer 16.

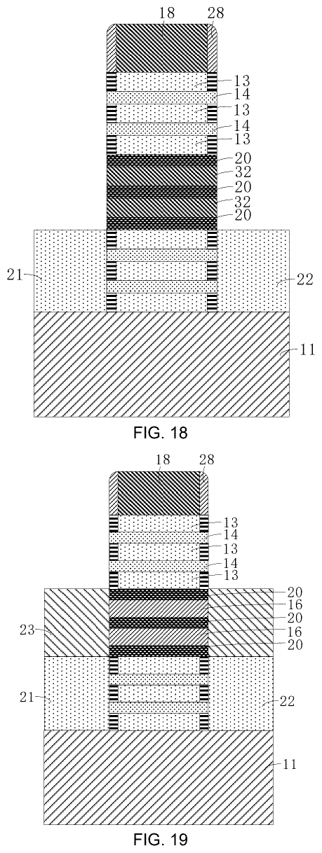

Next, as shown in FIG. 17 and FIG. 18, a first source region 21 and a first drain region 22 may be formed on both sides of the remaining first sacrificial layers 13 and channel layers 14 located below the remaining first middle dielectric isolation layers 20, respectively, by a process such as epitaxy. The materials of the first source region 21 and the first drain region 22 may be set according to actual needs, and are not specifically limited here.

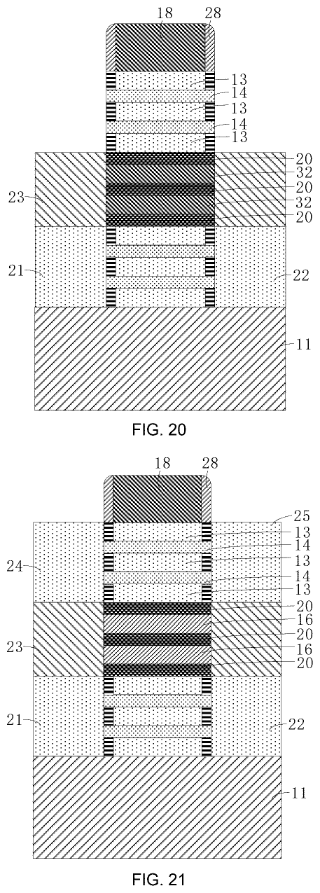

Next, as shown in FIG. 19 and FIG. 20, an insulating layer 23 may be formed on the first source region 21 and the first drain region 22 by processes such as deposition and etching. The thickness and material of the insulating layer 23 may be set according to actual needs.

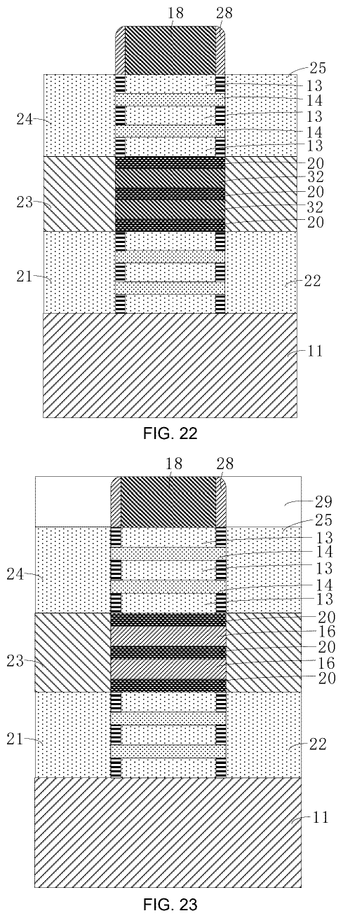

Next, as shown in FIG. 21 and FIG. 22, a second source region 24 and a second drain region 25 may be formed on the insulating layer 23 and on both sides of the remaining first sacrificial layers 13 and channel layers 14 located above the remaining first middle dielectric isolation layers 20, respectively, by a process such as epitaxy. The conductivity type of the second source region 24 and the second drain region 25 is opposite to the conductivity type of the first source region 21 and the first drain region 22. The materials of the second source region 24 and the second drain region 25 may be set according to actual needs, and are not specifically limited here. The materials of the second source region 24 and the second drain region 25 may be the same as or different from the materials of the first source region 21 and the first drain region 22.

In addition, after forming the second source region and the second drain region, the method may further include: as shown in FIG. 23 and FIG. 24, the interlayer dielectric layer 29 covering the semiconductor substrate 11 may be formed by processes such as deposition and planarization, so as to protect the second source region 24 and the second drain region 25 from operations such as etching and cleaning during subsequent operations, and improve the yield of the semiconductor device. The top of the interlayer dielectric layer 29 is flush with the top of the mask 18. The material of the interlayer dielectric layer 29 may include any dielectric material such as silicon oxide or silicon nitride.

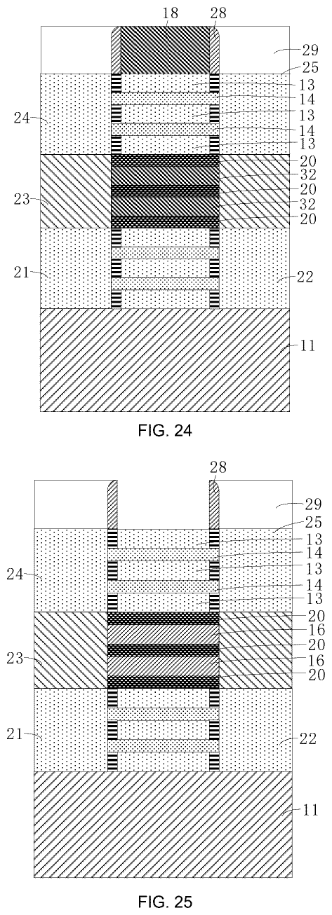

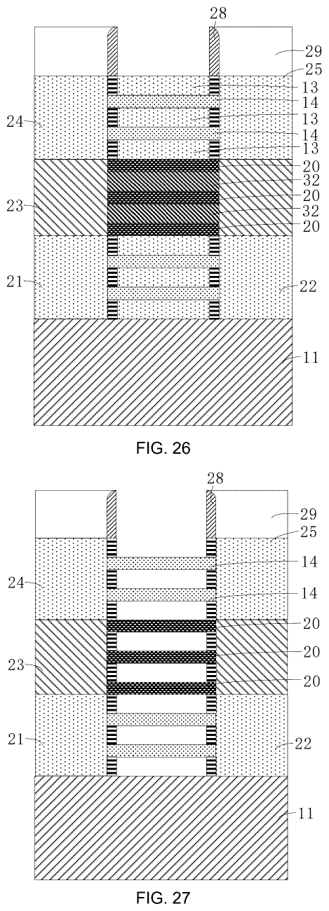

Next, as shown in FIG. 25 and FIG. 26, the mask may be removed by a process such as dry etching or wet etching. For example, the exposed structure may be determined according to the previous operation steps.

For example, as shown in FIG. 9, if the second middle dielectric isolation layer is not formed, the structures exposed by removing the mask 18 have the remaining first sacrificial layers 13 and the remaining third sacrificial layer 16. In this case, as shown in FIG. 27, the remaining first sacrificial layers 13 may be removed and the remaining third sacrificial layer 16 may be removed by a process such as dry etching or wet etching. Next, as shown in FIG. 31, a gate stack 30 surrounding at least the outer periphery of the remaining channel layers 14 is formed by a process such as atomic layer deposition. At this point, if the number of layers of the second sacrificial layer 15 is at least two, the gate stack 30 further surrounds the outer periphery of the remaining first middle dielectric isolation layers 20. The gate stack 30 may include a gate dielectric layer, and a gate electrode on the gate dielectric layer. The material of the gate dielectric layer may be an insulating material having a low dielectric constant such as silicon oxide or silicon nitride, or may be an insulating material having a high dielectric constant such as HfO₂, ZrO₂, TiO₂, or Al₂O₃. The material of the gate electrode may be a conductive material such as doped polysilicon, TiN, TaN, or TiSiN. The thicknesses of the above-described gate dielectric layer and gate electrode may be set according to actual needs, and are not specifically limited here. In addition, the materials and/or thicknesses of the gate stacks 30 included in the three-dimensional stacked complementary transistors may be the same or different.

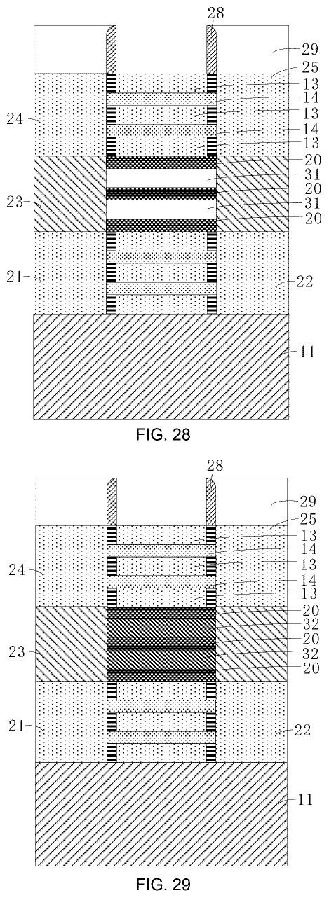

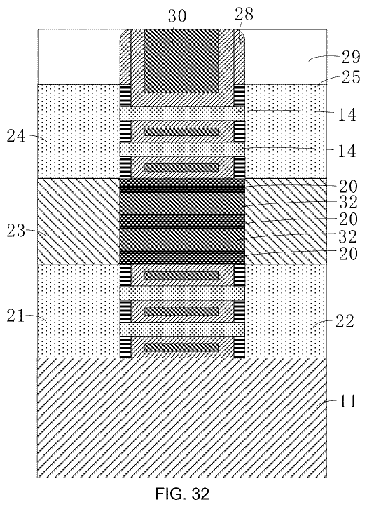

Alternatively, in this case (the above-described second middle dielectric isolation layer is not formed), when the material of the first sacrificial layer is different from the material of the third sacrificial layer, after removing the mask and before removing the remaining first sacrificial layers, the above-described method may include: removing the third sacrificial layer to form the third dielectric filling region 31 as shown in FIG. 28. Next, as shown in FIG. 29, the second middle dielectric isolation layer 32 is formed in the third dielectric filling region by processes such as deposition and etching. At this point, after the gate stack is formed, as shown in FIG. 32, the gate stack 30 only surrounds the outer periphery of the remaining channel layers 14 to reduce the parasitic capacitance. In addition, another alternative solution for reducing the parasitic capacitance may be provided, and the applicability of the manufacturing method provided by the embodiments of the present disclosure in different application scenarios may be improved.

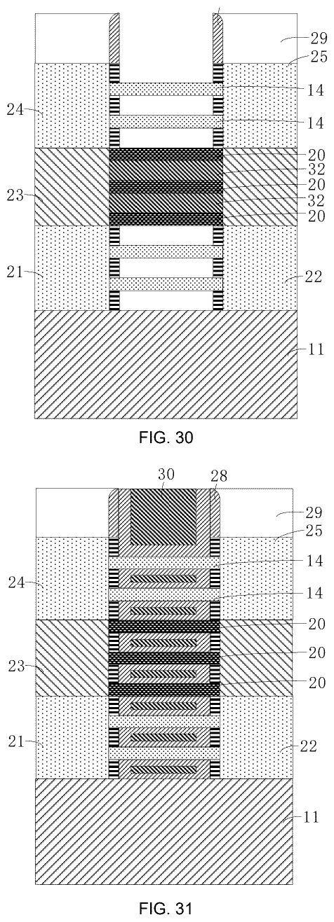

For example, as shown in FIG. 10 and FIG. 26, if the above-described second middle dielectric isolation layer 32 is formed before the first source region 21 and the first drain region 22 are formed, the structures exposed by removing the mask 18 have the remaining first sacrificial layers 13 and the remaining second middle dielectric isolation layer 32. Meanwhile, after the mask 18 is removed, the method may further include: removing the remaining first sacrificial layers by a process such as dry etching or wet etching as shown in FIG. 30. Next, as shown in FIG. 32, a gate stack 30 surrounding the outer periphery of the remaining channel layers 14 is formed by a process such as atomic layer deposition.

It should be noted that, as shown in FIG. 10, when the materials of the first sacrificial layer 13 and the third sacrificial layer 16 are different, if the above-described second middle dielectric isolation layer 32 is formed before forming the first source region and the first drain region, only the alternately stacked first sacrificial layers 13 and the channel layers 14 and the alternately stacked first middle dielectric isolation layers 20 and the second middle dielectric isolation layers 32 need to be etched in the process of source-drain etching. Since the first middle dielectric isolation layers 20 and the second middle dielectric isolation layers 32 are both dielectric isolation layers, compared with the difficulty of etching the alternately stacked first middle dielectric isolation layers 20 and the third sacrificial layer 16, the difficulty of etching the alternately stacked first middle dielectric isolation layers 20 and the second middle dielectric isolation layers 32 is lower, and the implementation is easier, which is beneficial to reducing the manufacturing difficulty.

In a case of adopting the above-described technical solution, as shown in FIG. 2 to FIG. 32, in the manufacturing method provided by the present disclosure, the first sacrificial layer 13, the second sacrificial layer 15, and the third sacrificial layer 16 have different functions. For example, in the subsequent process, the remaining channel layer 14 (the remaining channel layer 14 is used to form the channel region) is released by selectively removing a portion of the first sacrificial layer 13 corresponding to a gate electrode formation region, so as to form a gate stack 30 surrounding the outer periphery of the remaining channel layer 14. In the subsequent process, a first middle dielectric isolation layer 20 for isolating the gate stack 30 of the upper layer element included in the three-dimensional stacked complementary transistors from the gate stack 30 of the lower layer element is formed by selectively etching the second sacrificial layer 15. As for the above-described third sacrificial layer 16, a gate stack 30 may be subsequently formed at a position where a portion of the third sacrificial layer 16 corresponding to the gate electrode formation region is located, or an insulating dielectric material for isolation may be formed at the position. Based on this, in the existing manufacturing methods, a sufficient etching selectivity ratio of the first sacrificial layer 13, the second sacrificial layer 15, and the third sacrificial layer 16 is achieved by completely limiting the material types of the three. However, in the manufacturing method provided by the present disclosure, when the material of one of the second sacrificial layer 15 and the third sacrificial layer 16 includes silicon or silicon germanium, and the material of the other of the second sacrificial layer 15 and the third sacrificial layer 16 includes silicon germanium or germanium, the difference of germanium content in the second sacrificial layer 15 and the third sacrificial layer 16 is less than 15%; at this point, the material difference between the second sacrificial layer 15 and the third sacrificial layer 16 is small, and the corresponding lattice difference between the second sacrificial layer 15 and the third sacrificial layer 16 is also small. When epitaxially growing the materials for manufacturing the second sacrificial layer 15 and the third sacrificial layer 16, the problems in the related art such as the need to consider stress distribution and stress matching between films due to the large material difference between the second sacrificial layer 15 and the third sacrificial layer 16 may be alleviated, and the limitation of the epitaxial critical thickness may be reduced. There is no need to form more layers of the second sacrificial layer 15 and the third sacrificial layer 16 with smaller thicknesses as in the existing manufacturing methods, or to form a fixed number of layers of the second sacrificial layer 15 and the third sacrificial layer 16 due to the limitation of the critical thickness, which results in a smaller thickness of the insulating layer used to isolate the first source region 21 and the first drain region 22 from the second source region 24 and the second drain region 25, preventing leakage.

As shown in FIG. 2 to FIG. 32, the second sacrificial layers 15 are doped with an etching auxiliary agent. With such a configuration, in the subsequent process, the second sacrificial layers 15 may be selectively removed at least under an accelerated etching effect of the etching auxiliary agent to form the first dielectric filling region 19, and at the same time, the third sacrificial layer 16 may be retained, thereby improving the yield of the semiconductor device. In addition, the manufacturing method provided by the embodiments of the present disclosure is to perform the formation operation of the first middle dielectric isolation layers 20 in advance before the source-drain etching is performed; at this point, although the aspect ratio of the fin 12 may still be large, even if the insulating dielectric material at the bottom of the gap between adjacent fins 12 is not cleanly removed in the process of etching the insulating dielectric material used for manufacturing the first middle dielectric isolation layers 20, the formation of the first source region 21 and the first drain region 22 of the subsequent lower layer element will not be affected, and the contact of the first source region 21 and the first drain region 22 of the lower layer element with the first channel region respectively will not be affected. Furthermore, the insulating dielectric material remaining at the bottom of the gap between adjacent fins 12 may further isolate different semiconductor devices formed based on different fins 12, which reduces the risk of leakage, and also facilitates improving the operating performance of the manufactured semiconductor device while increasing the yield of the manufactured semiconductor device.

In the above descriptions, technical details such as patterning and etching of each layer have not been described in detail. However, those skilled in the art should understand that various technical means may be used to form layers, regions, etc. of desired shapes. In addition, in order to form the same structure, those skilled in the art may also design a method that is not completely the same as the method described above. Furthermore, although the various embodiments are described above separately, this does not mean that the measures in the various embodiments may not be advantageously used in combination.

The embodiments of the present disclosure have been described above. However, these embodiments are for clarity of illustration only, and are not intended to limit the scope of the present disclosure. The scope of the present disclosure is defined by the appended claims and their equivalents. Without departing from the scope of the present disclosure, those skilled in the art may make various substitutions and modifications, and these substitutions and modifications should all fall within the scope of the present disclosure.

What is claimed is:

1. A method of manufacturing a semiconductor device, comprising:
forming a fin on a semiconductor substrate, wherein the fin comprises first sacrificial layers and channel layers alternately stacked in a thickness direction of the semiconductor substrate, and second sacrificial layers and a third sacrificial layer alternately stacked in the thickness direction of the semiconductor substrate; the alternately stacked first sacrificial layers and the channel layers are located on both sides of the alternately stacked second sacrificial layers and the third sacrificial layer in the thickness direction of the semiconductor substrate; a bottom film layer and a top film layer among the alternately stacked first sacrificial layers and the channel layers are the first sacrificial layers, and a bottom film layer and a top film layer among the alternately stacked second sacrificial layers and the third sacrificial layer are the second sacrificial layers; a material of one of the second sacrificial layer and the third sacrificial layer comprises silicon or silicon germanium, and a material of the other of the second sacrificial layer and the third sacrificial layer comprises silicon germanium or germanium; a difference between a germanium content of the second sacrificial layer and a germanium content the third sacrificial layer is less than 15%, and the second sacrificial layer is doped with an etching auxiliary agent;
forming a mask straddling the fin;
selectively removing the second sacrificial layers at least under an accelerated etching effect of the etching auxiliary agent to form a first dielectric filling region, and retaining the third sacrificial layer;
forming first middle dielectric isolation layers in the first dielectric filling region;
removing the first sacrificial layers, the channel layers, the first middle dielectric isolation layers, and the third sacrificial layer not covered by the mask;
forming a first source region and a first drain region on both sides of the remaining first sacrificial layers and channel layer located below the remaining first middle dielectric isolation layers, respectively;
forming an insulating layer on the first source region and the first drain region; and
forming a second source region and a second drain region on the insulating layer and on both sides of the remaining first sacrificial layers and channel layer located above the remaining first middle dielectric isolation layers, respectively,
wherein a conductivity type of the second source region and the second drain region is opposite to a conductivity type of the first source region and the first drain region.

2. The method according to claim 1, wherein the etching auxiliary agent is an N-type dopant; and/or
wherein the method further comprises selectively removing the second sacrificial layers by using a wet etching process or an isotropic dry etching process; and/or
wherein a doping concentration of the etching auxiliary agent in the second sacrificial layer is greater than or equal to 1E18cm⁻³ and less than or equal to 1E19cm⁻³.

3. The method according to claim 1, wherein in a case that the second sacrificial layers are selectively removed by using a wet etching process, a wet etching solution comprises a mixed solution of hydrofluoric acid and hydrogen peroxide; or
in a case that the second sacrificial layers are selectively removed by using a dry etching process, an etching gas comprises a mixed gas of CF₄, O₂, and He.

4. The method according to claim 1, wherein a thickness of the second sacrificial layer and/or the third sacrificial layer is greater than or equal to 10 nm and less than or equal to 30 nm; and/or
wherein the method further comprises doping the etching auxiliary agent into the second sacrificial layer by using an in-situ doping method.

5. The method according to claim 1, wherein a material of the second sacrificial layer is the same as a material of the third sacrificial layer; and/or
a material of the first sacrificial layer is the same as a material of the third sacrificial layer.

6. The method according to claim 1, wherein after the removing the first sacrificial layers, the channel layers, the first middle dielectric isolation layers, and the third sacrificial layer not covered by the mask, and before the forming a first source region and a first drain region on both sides of the remaining first sacrificial layers and channel layer located below the remaining first middle dielectric isolation layers, respectively,
the method further comprises:
removing, along a length direction of the fin, edge portions on both sides of each of the remaining first sacrificial layers to form a second dielectric filling region; and
forming an inner spacer in the second dielectric filling region.

7. The method according to claim 1, wherein the mask includes a sacrificial gate; and/or
wherein the method further comprises forming, along a length direction of the fin, a gate spacer at least on both sides of the mask, when forming the first middle dielectric isolation layers in the dielectric filling region.

8. The method according to claim 1, wherein a material of the first middle dielectric isolation layer comprises at least one of SiN, SiCO, or SiCON.

9. The method according to claim 1, wherein after forming the second source region and the second drain region,
the method further comprises:
forming an interlayer dielectric layer covering the semiconductor substrate;
removing the mask;
removing the remaining first sacrificial layers and removing the remaining third sacrificial layer; and
forming a gate stack at least surrounding an outer periphery of the remaining channel layers.

10. The method according to claim 9, wherein a material of the first sacrificial layer is different from a material of the third sacrificial layer,
after removing the mask and before removing the remaining first sacrificial layers, the method further comprises:
removing the third sacrificial layer to form a third dielectric filling region; and
forming a second middle dielectric isolation layer in the third dielectric filling region.

11. The method according to claim 1, wherein a material of the first sacrificial layer is different from a material of the third sacrificial layer,
wherein after the forming first middle dielectric isolation layers in the first dielectric filling region, and before the forming a first source region and a first drain region on both sides of the remaining first sacrificial layers and channel layer located below the remaining first middle dielectric isolation layers, respectively, the method further comprises:
selectively removing the third sacrificial layer to form a third dielectric filling region;
forming a second middle dielectric isolation layer in the third dielectric filling region; and
removing the first sacrificial layers, the channel layers, the first middle dielectric isolation layers, and the second middle dielectric isolation layer not covered by the mask, and
wherein after forming the second source region and the second drain region, the method further comprises:
forming an interlayer dielectric layer covering the semiconductor substrate;
removing the mask;
removing the remaining first sacrificial layers; and
forming a gate stack surrounding an outer periphery of the remaining channel layers.

12. The method according to claim 10, wherein a material of the second middle dielectric isolation layer is the same as a material of the first middle dielectric isolation layer; or
a dielectric constant of a material of the second middle dielectric isolation layer is less than a dielectric constant of a material of the first middle dielectric isolation layer; and/or
a material of the first middle dielectric isolation layer comprises at least one of SiO₂, SiN, SiCO, SiCON, or SiO₂—SiF₄.
